(19) United States
(12) Patent Application Publication
(10) Pub. No.: US 2017/0288172 A1
(43) Pub. Date: Oct. 5, 2017

(54) Thin Film Packaging Structure, Method For Fabrication Thereof And Display Device

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Jiuxia YANG, Beijing (CN); Feng BAI, Beijing (CN); Yingzi WANG, Beijing (CN)

(21) Appl. No.: 15/511,521

(22) PCT Filed: Apr. 6, 2016
(86) PCT No.: PCT/CN2016/078538

§ 371 Date: Mar. 15, 2017

(30) Foreign Application Priority Data
May 14, 2015 (CN) 201510246548.9

(51) Int. Cl. H01L 51/52; H01L 51/56; H01L 27/32

(52) U.S. Cl. CPC H01L 51/5253; H01L 27/3244; H01L 51/56

(57) ABSTRACT

Embodiments of the disclosure provide a thin film packaging structure comprising a flexible thin film used for covering a device, wherein the flexible thin film comprises at least two organic film layers and at least one inorganic film layer, the at least two organic film layers comprises a first organic film layer and a second organic film layer, an inorganic film layer is provided between the first organic film layer and the second organic film layer, the first organic film layer contacts the device, and the second organic film layer is provided at an outermost layer of the flexible thin film. The thin film packaging structure according to embodiments of the disclosure can effectively prevent external oxygen and water from penetrating into the device and satisfy the packaging performance of the device.

### CROSS REFERENCE TO RELATED APPLICATIONS

This application is a National Stage entry of PCT/CN2016/078538 filed on Apr. 6, 2016, which claims priority to Chinese patent application number 201510246548.9, which was filed on May 14, 2015, both of which are incorporated by reference herein in its their entirety as part of the present application.

### TECHNICAL FIELD

The embodiments of the disclosure relate to a thin film packaging structure, a method for fabrication thereof and a display device.

### BACKGROUND OF THE INVENTION

In general, most of devices such as an organic light-emitting display are required to be packaged to protect the device and isolate it from the external environment (such as water and air) or for other requirements, etc. For example, the organic light-emitting display is an active light-emitting device which has the advantages of thin and light, wide angle of view, low power dissipation, fast response speed, capable of flexible display, therefore it has been widely used in the display field and lighting field.

The core parts of the organic light-emitting display are organic light-emitting devices (OLED) which are a new type of display device and have the advantages of good color saturation and wide angle of view. However a light-emitting material and a function material within the display device are sensitive to water and air. For example, the parameter requirements of water-tolerant and air-tolerant of its corresponding product are that the sealing requirement for oxygen is less than 10⁻³ cc/m²·day and the water resistance requirement is less than 10⁻⁶ g/m²·day.

Therefore, it is desirable to provide a package structure for protecting the device to be packaged.

### SUMMARY OF THE INVENTION

Embodiments of the disclosure provide a thin film packaging structure, a method for fabrication thereof and a display device, which can solve at least the following problem: the organic light-emitting display device is easy to be eroded by water and oxygen.

According to the first aspect of the disclosure, there is provided a thin film packaging structure comprising a flexible thin film used for covering a device, wherein the flexible thin film comprises at least two organic film layers and at least one inorganic film layer, the at least two organic film layers comprises a first organic film layer and a second organic film layer, the inorganic film layer is provided between the first organic film layer and the second organic film layer, the first organic film layer contacts the device, and the second organic film layer is provided at an outermost layer of the flexible thin film.

According to an embodiment of the disclosure, the flexible thin film comprises more than two inorganic film layers, the organic film layers and the inorganic film layers are provided alternately and each inorganic film layer is located between two organic film layers.

According to an embodiment of the disclosure, a sum of number of the organic film layer and the inorganic film layer is three to nine.

According to an embodiment of the disclosure, a material of the inorganic film layer comprises an inorganic nano-material.

According to an embodiment of the disclosure, an inorganic nano-material is dispersed within ethylenically unsaturated monomer.

According to an embodiment of the disclosure, photoinitiator and/or wetting leveling agent are added in the inorganic film layer.

According to an embodiment of the disclosure, a material of the organic film layers comprises one or combination of polyvinyl alcohol, polyurethane acrylate polymer and polyimide resin.

According to the second aspect of the disclosure, there is provided a display device comprising a light-emitting display device and the above thin film packaging structure covering on the light-emitting display device.

According to the third aspect of the disclosure, there is provided a method for fabricating a thin film packaging structure. The method comprises fabricating a flexible thin film comprising at least two organic film layers and at least one inorganic film layer, wherein the at least two organic film layers comprises a first organic film layer and a second organic film layer, wherein fabricating the flexible thin film comprises:

fabricating the first organic film layer on a device;

fabricating the inorganic film layer on the first organic film layer;

fabricating the second organic film layer, wherein the second organic film layer is located at an outermost layer of the flexible thin film.

According to an embodiment of the disclosure, the organic film layer is fabricated by using coating process, inkjet printing process or chemical vapor deposition process and performing curing.

According to an embodiment of the disclosure, the inorganic film layer is formed by coating inorganic material solution on the organic film layer, then baking and curing by employing ultraviolet curing process; or the inorganic film layer is fabricated by performing atomic layer deposition process on the organic film layer.

According to an embodiment of the disclosure, a baking temperature is 50-70 degree centigrade and a duration is 60-90 seconds.

From the above embodiments, the thin film packaging structure according to embodiments of the disclosure, by providing alternatively the organic film layer and the inorganic film layer, can effectively prevent external oxygen and water from penetrating into the device such as the organic light-emitting display device and satisfy the packaging performance of the device such as the organic light-emitting display device. The thin film packaging structure and process according to embodiments of the disclosure may be applied to the packaging of the device such as flexible display device.

### BRIEF DESCRIPTION OF THE DRAWINGS

In order to illustrate the technique solution of embodiments of the present disclosure more clearly, the accompanying drawings will hereinafter be introduced briefly. It is obvious that the accompanying drawings in the following description are only related to some embodiments of the present disclosure and should not be construed as restriction on the present disclosure.

FIG. 1 is a schematic structure diagram of a thin film packaging structure according to an embodiment of the disclosure;

FIG. 2 is a schematic structure diagram of a thin film packaging structure according to another embodiment of the disclosure; and

FIG. 3 is a flow chart of method for fabricating a thin film packaging structure according to an embodiment of the disclosure.

### DETAILED DESCRIPTION OF SPECIFIC EMBODIMENTS

To make the objects, technical solutions and advantages of embodiments of the present disclosure more clear, the technical solutions of embodiments of the present disclosure will be described below clearly and completely in connection with the accompanying drawings of embodiments of the present disclosure. It is obvious that the described embodiments are only some, but not all the embodiments of the present disclosure. Based on the embodiments of the disclosure, all the other embodiments made by those of ordinary skill in the art without the premise of creative work belong to the scope of protection of the disclosure.

It is noted that though the embodiments of the disclosure are mainly described in the context of the organic light-emitting display device, it can be understood by those skilled in the art that the embodiments of the disclosure may be applied to any other suitable devices, rather than only limited to the organic light-emitting display device.

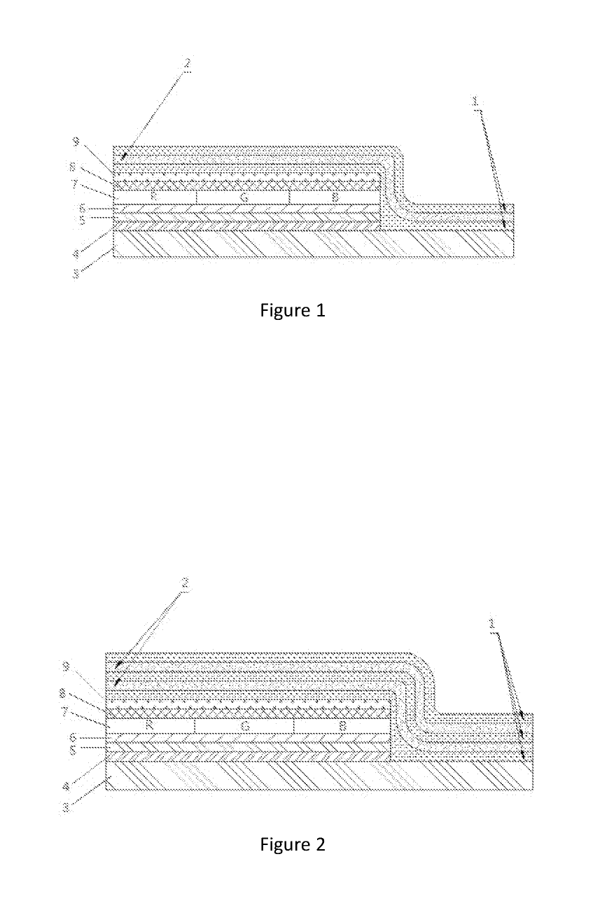

FIG. 1 is a schematic structure diagram of a thin film packaging structure according to an embodiment of the disclosure. As shown in FIG. 1, the thin film packaging structure according to the embodiment comprises a flexible thin film 100 used for covering a device such as an organic light-emitting display device, wherein the flexible thin film 100 comprises at least two organic film layers 1 and at least one inorganic film layer 2, the at least two organic film layers comprises a first organic film layer and a second organic film layer, the inorganic film layer 2 is provided between the first organic film layer and the second organic film layer, the first organic film layer contacts the device such as the organic light-emitting display device, and the second organic film layer is provided at an outermost layer of the flexible thin film.

A material of the inorganic film layer comprises an inorganic nano-material, wherein an inorganic nano-material comprises one or combination of aluminum oxide, zinc oxide, titanium oxide, silica, silicon nitride, and zirconia.

In an embodiment, the inorganic nano-material is dispersed within ethylenically unsaturated monomer. In other embodiments, the inorganic nano-material is dispersed evenly within ethylenically unsaturated monomer.

The inorganic nano-material is dispersed within ethylenically unsaturated monomer such that the inorganic nano-material and the ethylenically unsaturated monomer realize the mutual mix of the inorganic material and the organic material.

The inorganic nano-material is cured in the mean time when curing the ethylenically unsaturated monomer by using ultraviolet light such that it can realize a good combination of the inorganic material and the organic material.

In an embodiment, photoinitiator and/or wetting leveling agent are added in the inorganic film layer.

The ethylenically unsaturated monomer belongs to a light curing material. Since the inorganic nano-material is dispersed within the ethylenically unsaturated monomer, the photoinitiator is required to be added in the inorganic film layer when curing the light curing material.

The photoinitiator is also known as photo sensitizer or light curing agent which can absorb light energy of certain wavelengths within ultraviolet region or visible region, generates free radicals, positive ions, etc., and initiate a monomer polymerization crosslinking-curing compound.

In addition, the added wetting leveling agent may be used to adjust the surface tension of the liquid mixture such that the flatness of the film is better when film-forming.

In an embodiment, a material of the organic film layers comprises one or combination of polyvinyl alcohol, polyurethane acrylate polymer and polyimide resin.

In addition to the flexible thin film 100, FIG. 1 further shows the composition and structure of the device (the organic light-emitting display device as shown in FIG. 1) covered by the flexible thin film 100, wherein a substrate is denoted by reference marker 3, an anode is denoted by reference marker 4, a hole injection layer is denoted by reference marker 5, a hole transport layer is denoted by reference marker 6, an organic light emitting layer is denoted by reference marker 7, an electron transfer layer is denoted by reference marker 8, and a cathode is denoted by reference marker 9.

In order to save material and process steps, a sum of number of the organic film layer and the inorganic film layer should not be too bigger. Preferably, the sum of number of the organic film layer and the inorganic film layer is 3-9 layers, for example 3, 5, 7 or 9 layers.

The thin film packaging structure for packaging the device such as the organic light-emitting display device according to the embodiments may, by employing a way of alternatively providing the organic film layer and the inorganic film layer, can effectively prevent external oxygen and water from penetrating into the organic light-emitting display device. In addition, the thin film packaging structure according to the embodiments can satisfy the product's reliability requirements by damp heat test verification. Moreover the thin film packaging structure according to the embodiments may be applied to the packaging of the flexible display device.

FIG. 2 is a schematic structure diagram of a thin film packaging structure according to another embodiment of the disclosure. As shown in FIG. 2, in the thin film packaging structure according to the embodiment, a flexible thin film 100 used for covering a device such as an organic light-emitting display device comprises three organic film layers 1 and two inorganic film layers 2, wherein the organic film layers 1 and the inorganic film layers 2 are provided alternatively, and each inorganic film layer 2 is located between two organic film layers 1. The organic film layer 1 is used to contact the device such as the organic light-emitting display device, and an outermost layer of the flexible thin film is the organic film layer 1.

FIG. 2 further shows the composition and structure of the device (the organic light-emitting display device as shown in FIG. 2) covered by the flexible thin film 100, wherein a substrate is denoted by reference marker 3, an anode is denoted by reference marker 4, a hole injection layer is denoted by reference marker 5, a hole transport layer is denoted by reference marker 6, an organic light emitting layer is denoted by reference marker 7, an electron transfer layer is denoted by reference marker 8, and a cathode is denoted by reference marker 9.

In other embodiments, in the thin film packaging structure, the flexible thin film 100 used for covering the device such as the organic light-emitting display device may comprise four organic film layers 1 and three inorganic film layers 2, or five organic film layers 1 and four inorganic film layers 2, which are not be shown in the Figures.

There is provided a display device according to an embodiment of the disclosure. The display device comprises a light-emitting display device such as the organic light-emitting display device and the above thin film packaging structure covering on the light-emitting display device. The display device according to the embodiment may see FIGS. 1 and 2. In FIGS. 1 and 2, reference markers 3-6 constitute the organic light-emitting display device, wherein a thin film packaging structure covers the organic light-emitting display device and comprises the organic film layers 1 and the inorganic film layer(s) 2 which are provided alternatively, the organic film layer 1 contacts the device, and an outermost layer of the flexible thin film is the organic film layer 1.

Since the thin film packaging structure according to the above embodiments may be applied to the packaging of flexible display device, the display device according to the embodiment may be the flexible display.

Since the display device according to the present embodiments uses the thin film packaging structure according to the above embodiments, it has a good water and oxygen resistance.

The display device according to the embodiments may be applied to products with the display functionality, such as mobile phone, electronic paper, tablet, video camera, camera, television, printer, etc.

There is provided a method for fabricating the thin film packaging structure according to an embodiment of the disclosure. The method comprises fabricating the flexible thin film comprising at least two organic film layers and at least one inorganic film layer, wherein the at least two organic film layers comprises a first organic film layer and a second organic film layer, wherein fabricating the flexible thin film comprises:

fabricating the first organic film layer on a device;

fabricating the inorganic film layer on the first organic film layer;

fabricating the second organic film layer, wherein the second organic film layer is located at an outermost layer of the flexible thin film.

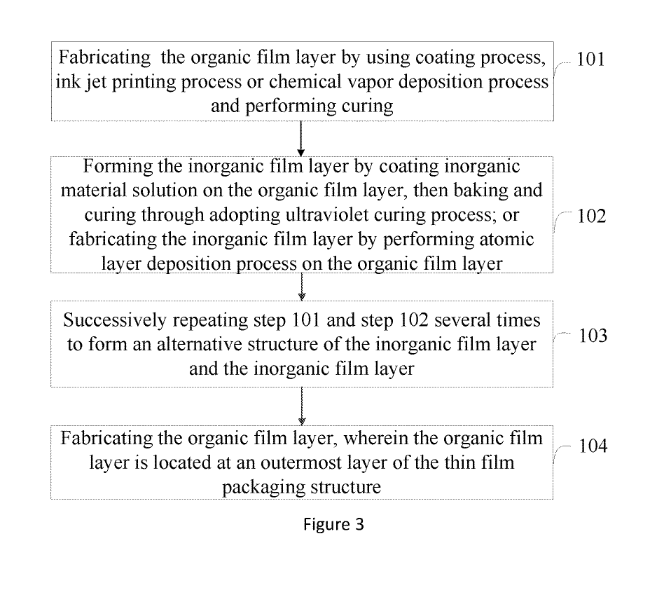

FIG. 3 is a flow chart of method for fabricating the thin film packaging structure according to an embodiment of the disclosure. With reference to FIG. 3, the method for fabricating a thin film packaging structure comprises:

Step 101: Fabricating the organic film layer by using coating process, ink jet printing process or chemical vapor deposition process and performing curing.

In step 101, the organic film layer is fabricated by, on the device such as the organic light-emitting display device, performing coating process, ink jet printing process or chemical vapor deposition process and performing curing. When fabricating the organic film layer, a material can be selected from one or combination of polyvinyl alcohol, polyurethane acrylate polymer and polyimide resin.

Step 102: forming the inorganic film layer by coating inorganic material solution on the organic film layer, then baking and curing through employing ultraviolet curing process; or fabricating the inorganic film layer by performing atomic layer deposition process on the organic film layer. A baking temperature is 50-70 degree centigrade and a duration is 60-90 seconds.

When fabricating the inorganic film layer, a material can be selected from one or combination of aluminum oxide, zinc oxide, titanium oxide, silica, silicon nitride, and zirconia. In an embodiment, an inorganic nano-material using above material is dispersed evenly within ethylenically unsaturated monomer. In addition, additive such as photoinitiator and/or wetting leveling agent is added within the inorganic nano-material.

The inorganic nano-material is dispersed within the ethylenically unsaturated monomer such that the inorganic nano-material and the ethylenically unsaturated monomer realize the mutual mix of the inorganic material and the organic material. The inorganic nano-material are cured in the mean time when curing the ethylenically unsaturated monomer by ultraviolet light such that it can realize a good combination of the inorganic material and the organic material.

The ethylenically unsaturated monomer belongs to light curing material. Since the inorganic nano-material is dispersed within the ethylenically unsaturated monomer, the photoinitiator may be required to be added in the inorganic nano-material when curing the light curing material. The photoinitiator can absorb light energy of certain wavelengths within ultraviolet region or visible region, generates free radicals, positive ions, etc., and initiate a monomer polymerization crosslinking-curing compound.

In addition, the added wetting leveling agent may be used to adjust the surface tension of the liquid mixture such that the flatness of the film is better when film-forming.

Step 103: successively repeating step 101 and step 102 several times to form an alternative structure of the inorganic film layer and the inorganic film layer.

Step 104: fabricating the organic film layer, wherein the organic film layer is located at an outermost layer of the thin film packaging structure.

In order to save material and process steps, a sum of number of the organic film layer and the inorganic film layer should not be too bigger. Preferably, the sum of number of the organic film layer and the inorganic film layer is 3-9 layers, for example 3, 5, 7 or 9 layers.

The method for fabricating the thin film packaging structure according to the embodiments may be used for fabricating the thin film packaging structure of above embodiments.

The thin film packaging structure fabricated by employing the fabricating method according to the embodiments may cover the device such as the organic light-emitting display device. The thin film packaging structure according to the embodiments can satisfy the product reliability requirements by damp heat test. The test proves that the thin film packaging structure can effectively prevent external oxygen and water from penetrating into the organic light-emitting display device and satisfy the packaging performance of the device such as the organic light-emitting display device. Moreover the thin film packaging structure and process according to embodiments of the disclosure may be applied to the packaging of flexible display device.

The embodiments above are only for illustrating the technical solutions of the disclosure rather than limiting the disclosure. Though the disclosure have been described in detail with reference to embodiments, it should be understood by those ordinary skilled in the art that various modifications and equivalent replacements of a part of technical features of the technical solution of above-mentioned embodiments of the disclosure can be made without departing from the spirit and scope of the disclosure, and these modifications and replacements should be deemed as within the protect scope of the disclosure.

1. A thin film packaging structure, comprising a flexible thin film used for covering a device, wherein the flexible thin film comprises at least two organic film layers and at least one inorganic film layer, the at least two organic film layers comprises a first organic film layer and a second organic film layer, the inorganic film layer is provided between the first organic film layer and the second organic film layer, the first organic film layer contacts the device, and the second organic film layer is provided at an outermost layer of the flexible thin film.

2. The thin film packaging structure according to claim 1, wherein the flexible thin film comprises more than two inorganic film layers, the organic film layers and the inorganic film layers are provided alternately and each inorganic film layer is located between two organic film layers.

3. The thin film packaging structure according to claim 1, wherein a sum of number of the organic film layer and the inorganic film layer is three to nine.

4. The thin film packaging structure according to claim 1, wherein a material of the inorganic film layer comprises an inorganic nano-material.

5. The thin film packaging structure according to claim 4, wherein the inorganic nano-material is dispersed within ethylenically unsaturated monomer.

6. The thin film packaging structure according to claim 1, wherein photoinitiator and/or wetting leveling agent are added in the inorganic film layer.

7. The thin film packaging structure according to claim 1, wherein a material of the organic film layers comprises one or combination of polyvinyl alcohol, polyurethane acrylate polymer and polyimide resin.

8. A display device comprising a light-emitting display device and the thin film packaging structure according to claim 1, wherein the thin film packaging structure covers on the light-emitting display device.

9. A method for fabricating a thin film packaging structure, comprising fabricating a flexible thin film comprising at least two organic film layers and at least one inorganic film layer, wherein the at least two organic film layers comprises a first organic film layer and a second organic film layer, wherein fabricating the flexible thin film comprises:
fabricating the first organic film layer on a device;
fabricating the inorganic film layer on the first organic film layer;
fabricating the second organic film layer, wherein the second organic film layer is located at an outermost layer of the flexible thin film.

10. The method for fabricating the thin film packaging structure according to claim 9, wherein the organic film layer is fabricated by using coating process, inkjet printing process or chemical vapor deposition process and performing curing.

11. The method for fabricating the thin film packaging structure according to claim 9, wherein the inorganic film layer is formed by coating inorganic material solution on the organic film layer, then baking and curing by employing ultraviolet curing process; or the inorganic film layer is fabricated by performing atomic layer deposition process on the organic film layer.

12. The method for fabricating the thin film packaging structure according to claim 11, wherein a baking temperature is 50-70 degree centigrade and a duration is 60-90 seconds.

13. The thin film packaging structure according to claim 2, wherein a sum of number of the organic film layer and the inorganic film layer is three to nine.

14. The thin film packaging structure according to claim 2, wherein a material of the inorganic film layer comprise an inorganic nano-material.

15. The thin film packaging structure according to claim 3, wherein a material of the inorganic film layer comprise an inorganic nano-material.

16. The thin film packaging structure according to claim 2, wherein photoinitiator and/or wetting leveling agent are added in the inorganic film layer.

17. The thin film packaging structure according to claim 3, wherein photoinitiator and/or wetting leveling agent are added in the inorganic film layer.

18. The thin film packaging structure according to claim 4, wherein photoinitiator and/or wetting leveling agent are added in the inorganic film layer.

19. The thin film packaging structure according to claim 5, wherein photoinitiator and/or wetting leveling agent are added in the inorganic film layer.

20. The thin film packaging structure according to claim 2, wherein a material of the organic film layers comprises one or combination of polyvinyl alcohol, polyurethane acrylate polymer and polyimide resin.
